(19) United States
(12) Patent Application Publication
(10) Pub. No.: US 2025/0139308 A1
(43) Pub. Date: May 1, 2025

(54) SEMANTIC HIERARCHICAL GEOMETRIC REPRESENTATIONS FOR DIGITAL TWINS

(71) Applicant: Dell Products L.P., Round Rock, TX (US)

(72) Inventors: Werner Spolidoro Freund, Rio de Janeiro (BR); Herberth Birck Fröhlich, Florianópolis (BR); Marcus Vinicius Libardi Pazini, Caxias do Sul (BR)

(21) Appl. No.: 18/495,961

(22) Filed: Oct. 27, 2023

(51) Int. Cl. G06F 30/10; G06N 20/00

(52) U.S. Cl. CPC G06F 30/10; G06N 20/00

(57) ABSTRACT

One example method includes performing geometrical modeling of a digital twin network that includes a dynamically informed digital twin of a near-edge node and dynamically informed digital twins of far-edge nodes. Each digital twin is defined by a set of geometrical modeling variables and contextual variables that are used to map each digital twin to a graph. The geometrical modeling includes obtaining measurements from sensors in an edge environment that includes the near-edge and the far-edge nodes; associating measurements to a digital twin node in the graph; updating the digital twin node in the graph associated with the measurements and updating the corresponding far-edge node with a local update; updating digital twin nodes associated with the digital twin node that was updated; and updating digital twin nodes not associated with the digital twin node that was updated.

### FIELD OF THE INVENTION

Embodiments of the present invention generally relate to edge environments. More particularly, at least some embodiments of the invention relate to systems, hardware, software, computer-readable media, and methods for positioning and mapping operations for dynamically informed digital twins representing edge nodes operating in the edge environment.

### BACKGROUND

Edge environments typically include a near-edge node and various far-edge nodes. The near-edge node typically includes more computing resources than the far-edge nodes and thus often will perform some processing tasks for the far-edge nodes. In addition, the near-edge node will often provide orchestration services to the far-edge nodes. These tasks can require large amounts of communication bandwidth. This can be problematic in an edge environment where the communication bandwidth is limited and/or the computing resources of the near-edge node are limited.

### BRIEF DESCRIPTION OF THE DRAWINGS

In order to describe the manner in which at least some of the advantages and features of the invention may be obtained, a more particular description of embodiments of the invention will be rendered by reference to specific embodiments thereof which are illustrated in the appended drawings. Understanding that these drawings depict only typical embodiments of the invention and are not therefore to be considered to be limiting of its scope, embodiments of the invention will be described and explained with additional specificity and detail through the use of the accompanying drawings.

FIG. 1 discloses aspects of an edge environment according to the embodiments disclosed herein;

FIG. 2 discloses aspects of an SO-map according to the embodiments disclosed herein;

FIG. 3 discloses aspects of a digital twin network according to the embodiments disclosed herein;

FIG. 4 discloses aspects of an edge environment that implements a digital twin network according to the embodiments disclosed herein;

FIG. 5 discloses aspects of contextual variables according to the embodiments disclosed herein;

FIG. 6 discloses aspects of a dynamically informed digital twin according to the embodiments disclosed herein;

FIG. 7 discloses aspects of near-edge digital twin according to the embodiments disclosed herein;

FIG. 8 discloses aspects of an SO-map of a digital twin network according to the embodiments disclosed herein;

FIG. 9 discloses aspects of updating SO-map of a digital twin network according to the embodiments disclosed herein;

FIG. 10 discloses aspects of associating measurements to digital twin nodes according to the embodiments disclosed herein;

FIG. 11 discloses aspects of creating digital twin nodes according to the embodiments disclosed herein;

FIG. 12 discloses aspects of updating digital twin nodes according to the embodiments disclosed herein;

FIG. 13 discloses aspects of updating associated digital twin nodes according to the embodiments disclosed herein;

FIG. 14 discloses aspects of updating other digital twin nodes according to the embodiments disclosed herein;

FIG. 15 discloses aspects of pruning digital twin nodes in the SO-map according to the embodiments disclosed herein; and

FIG. 16 discloses aspects of a computing device, system, or entity according to the embodiments disclosed herein.

### DETAILED DESCRIPTION OF SOME EXAMPLE EMBODIMENTS

Embodiments of the present invention generally relate to edge environments. More particularly, at least some embodiments of the invention relate to systems, hardware, software, computer-readable media, and methods for positioning and mapping operations for dynamically informed digital twins representing edge nodes operating in the edge environment.

One example method includes performing geometrical modeling of a digital twin network that includes a dynamically informed digital twin of a near-edge node and dynamically informed digital twins of far-edge nodes. Each digital twin is defined by a set of geometrical modeling variables and contextual variables that are used to map each digital twin to a graph. The geometrical modeling includes obtaining measurements from sensors in an edge environment that includes the near-edge and the far-edge nodes; associating measurements to a digital twin node in the graph; updating the digital twin node in the graph associated with the measurements and updating the corresponding far-edge node with a local update; updating digital twin nodes associated with the digital twin node that was updated; and updating digital twin nodes not associated with the digital twin node that was updated.

Embodiments of the invention provide for each semantic object in the environment to be represented by a digital twin in the network. The network captures their association structure in the form of a hierarchy. The network structure is leveraged to keep a multi-resolution description of the environment state, with digital twins in the lower layers of the network keeping a less precise description of the environment state. The precision of the geometric modelling of each digital twin in the network is dynamically determined as a function of contextual properties.

Embodiments of the invention keep a multi-resolution global state of the environment readily available to be provided on-demand and/or processed at the required level-of-detail by leveraging semantic information.

Embodiments of the invention enable resource efficient representation. The proposed representation builds on OctoMaps and Octree Hierarchies in a manner that reduces resource constraints. Further, information is readily available for processing as parent nodes keep a simpler representation of the environment.

The disclosed representation builds upon two efficient 3D map solutions: OctoMap and Octree Hierarchy. By addressing their limitations, embodiments of the invention define a method to reduce resource strains to execute the algorithms in the near-edge node.

Further, embodiments of the invention support multiple resolutions. Applications requiring higher level-of-detail for determined semantics or nodes can acquire such information by accessing the information on the graph.

Embodiments of the invention, such as the examples disclosed herein, may be beneficial in a variety of respects. For example, and as will be apparent from the present disclosure, one or more embodiments of the invention may provide one or more advantageous and unexpected effects, in any combination, some examples of which are set forth below. It should be noted that such effects are neither intended, nor should be construed, to limit the scope of the claimed invention in any way. It should further be noted that nothing herein should be construed as constituting an essential or indispensable element of any invention or embodiment. Rather, various aspects of the disclosed embodiments may be combined in a variety of ways so as to define yet further embodiments. Such further embodiments are considered as being within the scope of this disclosure. As well, none of the embodiments embraced within the scope of this disclosure should be construed as resolving, or being limited to the resolution of, any particular problem(s). Nor should any such embodiments be construed to implement, or be limited to implementation of, any particular technical effect(s) or solution(s). Finally, it is not required that any embodiment implement any of the advantageous and unexpected effects disclosed herein.

It is noted that embodiments of the invention, whether claimed or not, cannot be performed, practically or otherwise, in the mind of a human. Accordingly, nothing herein should be construed as teaching or suggesting that any aspect of any embodiment of the invention could or would be performed, practically or otherwise, in the mind of a human. Further, and unless explicitly indicated otherwise herein, the disclosed methods, processes, and operations, are contemplated as being implemented by computing systems that may comprise hardware and/or software. That is, such methods processes, and operations, are defined as being computer-implemented.

### A. Aspects of an Edge Environment

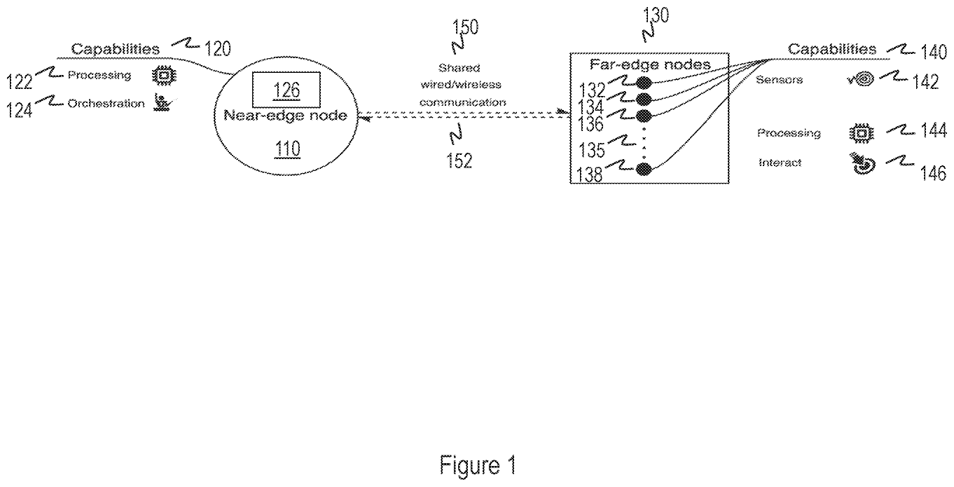

The embodiments disclosed herein may be practiced in an edge environment, although this is not required as the embodiments disclosed herein are not limited to any particular environment. Accordingly, a short explanation of an edge environment 100 will now be provided in relation to FIG. 1. As illustrated in FIG. 1, the edge environment 100 includes a near-edge node 110 and multiple far-edge nodes 130. The near-edge node 110 has various capabilities 120. For example, the near-edge node 110 has processing capabilities 122 that allow the near-edge node 110 to provide processing for itself and for one or more of the far-edge nodes 130. In addition, the near-edge node 110 has orchestration capabilities 124 that allow the near-edge node 110 to orchestrate the operation of one or more of the far-edge nodes 130. The near-edge node 110 further has data storage capabilities 126. It will be appreciated that the near-edge node 110 can include additional capabilities that are not illustrated. In one embodiment, the near-edge node 110 is a central node of a warehouse that orchestrates the operation of various far-edge nodes that are autonomous mobile robots (AMR) or smart forklifts.

As illustrated in FIG. 1, the edge environment 100 includes the various far-edge nodes 130. For example, the edge environment includes a far-edge node 132, a far-edge node 134, a far-edge node 136, a far-edge node 138, with the ellipses 135 illustrating that there can be any number of additional far-edge nodes 130. Each of the far-edge nodes 130 includes various capabilities 140. For example, the far-edge nodes 130 include sensors 142 that allow the far-edge node to monitor its surroundings or to monitor its operation. The far-edge nodes 130 also include processing capabilities 144, which allow the far-edge node to perform local processing. It will be noted that in many embodiments, the processing capabilities 144 are not as large as the processing capabilities 122 of the near-edge node 110. Accordingly, the far-edge nodes 130 can utilize the processing capabilities 122 as needed. The far-edge nodes 130 also have interaction capabilities 146 that allow the far-edge nodes the ability to interact with their surroundings and with other far-edge nodes. Although not illustrated, the far-edge nodes also include data storage capabilities and other additional capabilities that are not illustrated. In one embodiment, the far-edge nodes 130 are the AMRs or smart forklifts operating in the warehouse of the near-edge node 110.

Accordingly, the far-edge nodes are sufficiently important assets in the edge environment 100. In some embodiments, the far-edge nodes include the sensors 142. However, in some cases, the sensors 142 can be restricted to measure the asset inner functioning status, for example the dynamics of a motor responsible for a production running machine. Some assets can provide information of their surroundings, for example security cameras, etc. This is also the case of some assets providing the ability to interact with the environment such as AMRs and smart forklifts. These assets can also respond to commands from the near-edge node 110, for example an AMR can be used to move some items of the inventory, a production running machine can be commanded to change its operation speed, etc.

To properly control the edge environment 100, the near-edge node 110 collects sensed information from the far-edge nodes 130 to monitor the environment operation and take orchestration decision that are communicated back to the far-edge nodes 130 using shared communication 150. The shared communication 150 can occur via multiple wired and/or wireless channels 152. The channels 152 can be shared by several far-edge nodes 130.

In the edge environment, environmental semantics refer to a set of objects or places with similar characteristics or functions such as robots, humans, pallets, products, forklifts, shelves, animals, trees etc. The semantical groups are defined by considering the application specificities. Tessellation of a space refers to its division in mutually exclusive regions. Some embodiments disclosed herein are based on 3D space hierarchical tessellation because of its large applicability in envisioned use cases.

Level-of-detail refers to the fidelity of the geometric modeling approach, i.e., its ability to precisely represent the physical environment state. On a 3D tessellated representation, it refers to how granular the tessellation on the 3D map representation is, e.g., higher level-of-detail implies in thinner tessellations. It is possible to achieve higher resource usage efficiency while maintaining enough information to perform the tasks by letting the level-of-detail to be a function of the semantics and of the processing algorithm, e.g., some algorithms (e.g., optimizing pathing) may require only limited level-of-detail that may vary with semantics (e.g., lowest level-of-detail for the background).

### B. Aspects of Geometrical Representation

### B.1. Octree Hierarchy

One aspect of the embodiments disclosed herein is the geometrical representation of the environmental state, which is used by the near-edge node to orchestrate tasks in the environment. The embodiments disclosed herein deal with the optimization of the geometrical representation of the environment in a digital twin framework processed in the near-edge node as will be explained in more detail to follow. While there are multiple approaches to perform hierarchical representation, it is noted that octree variants are mostly appliable for their simplicity, performance, and framework availability.

Octree Hierarchy shows that using semantic information for optimizing the tessellation structure of OctoMaps is useful to greatly reduce the memory and processing requirements of representing and manipulating information in an OctoMap framework. An example application has shown memory and runtime for building the complete map reduced respectively by a lower bounding factor of 10× and 4×. The example contained three semantics: objects to be manipulated at 2 mm resolution, a table at 10 mm and the background at 50 mm resolution.

### B.2. Aspects of an SO-Map

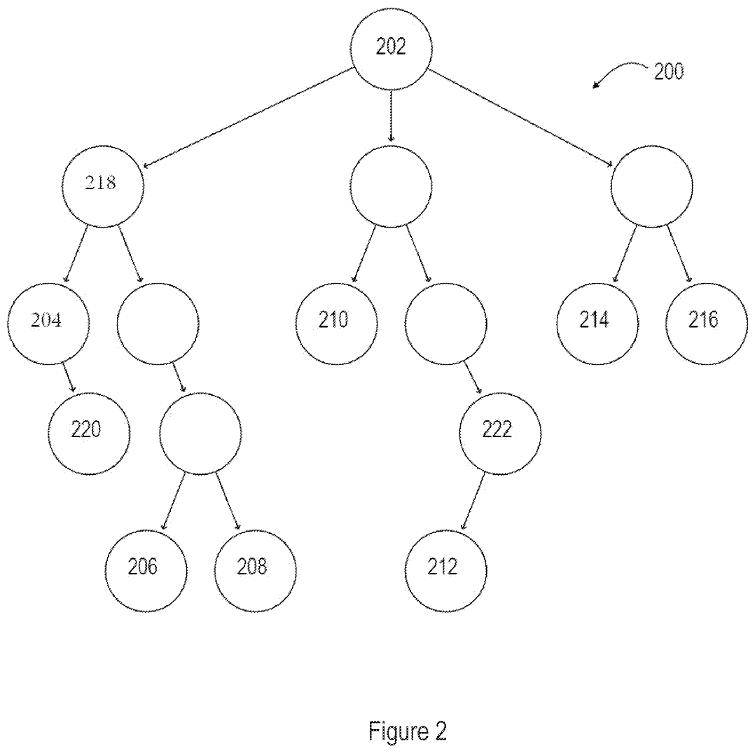

FIG. 2 illustrates an example of graph 200 implemented as an SO-Map. The graph 200 includes a root graph node 202. The root graph node 202 is a lowest depth node of the graph 200 and the leaf graph nodes 220, 206, 208, 210, and 212 refer to graph nodes without child nodes. The depth d of the graph 200 can be arbitrarily large. The relationships of objects in an environment may vary and change continually. However, the graph 200 allows information to be received and distributed efficiently and in a manner that better utilizes available resources at the near-edge and far-edge nodes.

A graph node may have a sextuplet form such as nᵢ=(mᵢ, tᵢ, pᵢ, Cᵢ, sᵢ, uᵢ), where, for a generic node nᵢ, mᵢ is a OctoMap, tᵢ is the reference frame of the node (6D transform), pᵢ is the parent node reference, Cᵢ is a set of references of child nodes, sᵢ is the semantic label and the term uᵢ, which is used to record the last time of update of the nᵢ node. The root graph node 202 may be n₀=(m₀, t₀, p₀=Ø, C₀={nᵢ|pᵢ=n₀}, l₀=Ø, u₀).

The graph node 218 may be represented by n₁=(m₁, t₁, p₁=n₀, C₁={nᵢ|pᵢ=n₁, l₁=shelf, u₁). This demonstrates that the graph 200 includes a semantic aspect and illustrates that, in some embodiments, each graph node may correspond to a specific device or object in the environment. In other words, each graph node corresponds to a far-edge node in one example. This allows relationships to be reflected in the graph 200 semantically. For example, the label l₂ of the node 204 may be pallet. Because the graph node 204 is a child of the graph node 218, this may reflect a relationship between the pallet and the shelf. In other words, the pallet is on the shelf. The label l₂ of the graph node 220 may be goods. This may reflect that the goods represented by the graph node 220 are on the pallet represented by the graph node 204, which is on the shelf represented by the graph node 218.

In another example, the label may also represent an interaction. For example, the label of the graph node 222 may be “open box” and the label of the graph node 212 may be goods. This may indicate that the box containing the goods is or has been opened. This may be a decision that was decided by the near-edge node and provided to an object or far-edge node that then opened the box. Opening the box is also an example of an interaction that may be reported back to the near-edge node. Opening the box may be performed in response to an instruction of decision and may also be reported as an interaction. The semantics in the graph represented that the box was not open. The interaction resulted in a map update such that the semantics and graph nodes represented that the box is open.

Additional details regarding an SO-Map is found in U.S. patent application Ser. No. 18/049,700, filed Oct. 26, 2022, and titled “SO-MAP: A SEMANTIC-AWARE ALGORITHM FOR OPTIMIZING THE REPRESENTATION STRUCTURE OF OCTOMAPS”, which is incorporated by reference herein in its entirety.

### C. Aspects of a Digital Twin Framework

The embodiments disclosed herein are related to a digital twin framework that can be executed at a near-edge node such as the near-edge node 110. Accordingly, a short explanation of a digital twin network will now be given. In general, a digital twin is a digital representation of an intended or actual real-world physical product, system, or process that serves as the effectively indistinguishable digital counterpart of it for practical purposes, such as simulation, integration, testing, monitoring, and maintenance.

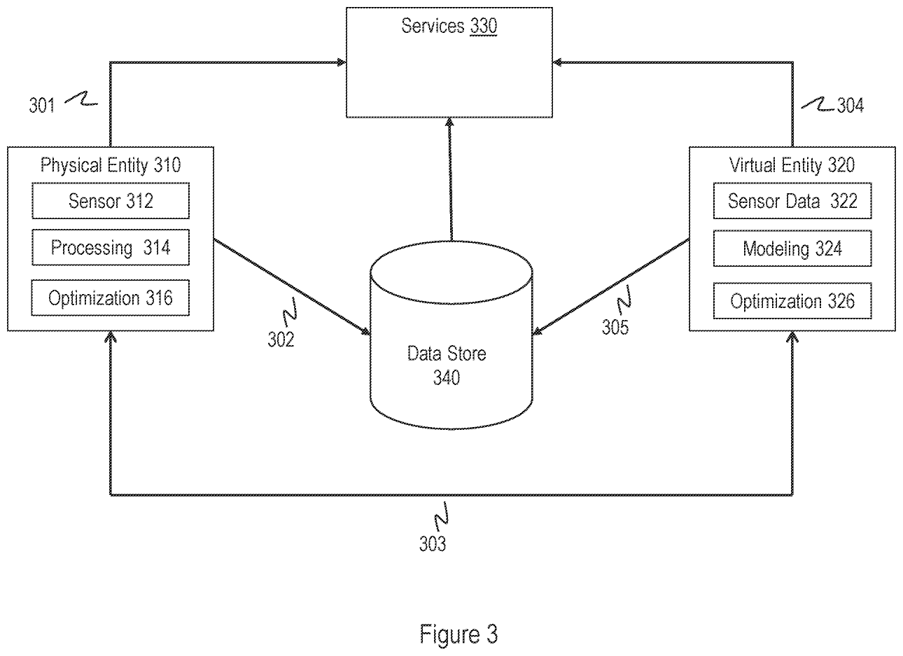

FIG. 3 illustrates an embodiment of a digital twin network 300. As illustrated, the digital twin network 300 includes a physical entity 310 and a virtual entity 320 that is a digital twin of the physical entity 310. The digital twin network 300 also includes services 330 and data store 340. The physical entity 310 is a real world device such as an AMR or a smart forklift. Accordingly, the physical entity 310 includes, but is not limited to, sensors 312 for monitoring its operational environment and its operational parameters, processing capabilities 314 that allow the physical entity to process data so that it can perform a primary task such as moving supplies in a warehouse, and optimization capabilities 316 that are used to optimize its primary task. The physical entity 310 is also able to access various services 330 as shown at 301 that it uses in the performance of its primary task and is able to access the data store 340 as shown at 302 to access data as needed.

The virtual entity 320 is able to virtually represent the physical entity 310 by maintaining a communication channel 303 with the physical entity. Accordingly, the virtual entity 320 includes sensor data 322 that includes data obtained from the sensors 312. The virtual entity also includes modeling capabilities 324 and optimization capabilities 326. The virtual entity 320 is able to use the modeling capabilities 324 and optimization capabilities 326 to model and optimize the primary task and other operational aspects of the physical entity 310 to thereby allow a user to determine optimal perforce parameters for the physical entity 310, which can then be fed back to the physical entity 310. The virtual entity 320 can also access the services 330 as shown at 304 and the data store 340 as shown at 305 so as to mirror the services and data accessed by the physical entity 310.

### C.1. Aspects of Dynamically Informed Digital Twins (DYDT)

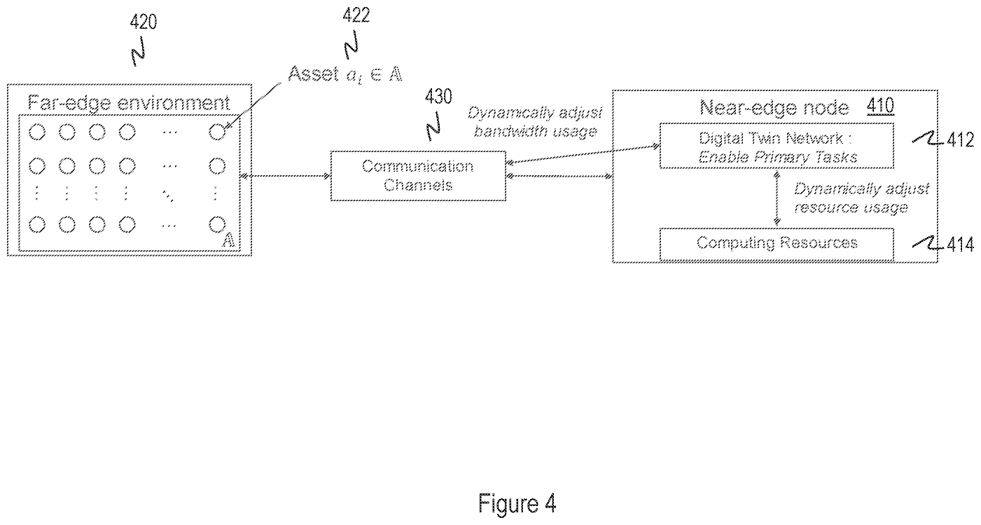

FIG. 4 illustrates an embodiment of an edge environment 400 that may correspond to the edge environment 100 previously described. Accordingly, the edge environment 400 includes a near-edge node 410, that may correspond to the near-edge node 110, and a far-edge environment [symbol] 420 that includes various far-edge nodes, which may correspond to the far-edge nodes 130, referred as far-edge assets in FIG. 4. Accordingly, as shown at 422, each far-edge node is a far-edge asset aᵢ∈ [symbol] . In the embodiment, the near-edge node 410 includes computing resources 414 that are used by the near-edge node to perform its primary tasks and may also be used by one or more of the far-edge assets 422. In addition, communication channels 430, which may be any reasonable wired or wireless communication channel, allow the near-edge node 410 to communicate with each of the far-edge assets 422.

In operation, however, the computing resources 414 and the bandwidth of the communication channels 430 may be limited. Accordingly, the principles of the embodiments disclosed herein provide for a dynamically informed digital twin network 412 to be implemented as the near-edge node 410. The dynamically informed digital twin network 412 includes virtual entities implemented at the near-edge node 410 that are the digital twins to physical entities that correspond to the each of the far-edge assets 422. Implementation of the dynamically informed digital twin network 412 allows the near-edge node 410 to dynamically adjust resource usage to reduce the impact on the primary tasks of the near-edge node and/or the various far-edge assets 422. In other words, use of the dynamically informed digital twin network 412 allows the near-edge node 410 to modify or adjust the amount of computing resources 414 that can be used by the near-edge node 410 and the various far-edge assets 422, commination channel bandwidth 430 that can be used by the near-edge node 410 and the various far-edge assets 422, and any data storage resources of the near-edge node 410 and/or the various far-edge assets 422 can also be instantiated or deallocated by the near-edge node 410 and the various far-edge assets 422. In particular, the dynamically informed digital twin network 412 dynamically adjusts the level of information acquired and processed within the network.

It will be noted that the dynamically informed digital twin network 412 may represent any arbitrary asset structure in the edge environment 400, thereby providing the means to enable any primary tasks to be executed with the environment information. Thus, the discussion of the embodiments disclosed herein will focus more on how the dynamically informed digital twin network 412 dynamically adjusts the information while reducing the impact on the primary tasks, rather than focusing on the specific way to execute the primary tasks, which can take the form that best suits the edge environment 400.

### C.2 Aspects of Contextual Variables

In the embodiments disclosed herein, there are two types of variables: (1) primary variables and (2) contextual variables. Primary variables are related to the primary task of the near-edge node 410 and/or the far-edge assets 422. For example, primary tasks of the near-edge node 410 is monitoring and orchestrating the far-edge assets 422 in the far-edge environment 420 [symbol] .

Contextual variables, on the other hand, represent relevant properties of the edge environment and are used in the embodiments disclosed herein to dynamically adjust resource usage in the edge environment. In some embodiments, the contextual variables may be interrelated with the primary variables. In some cases, the contextual variables are proxies to the quality, precision, or trustworthiness of the primary variables as usually one can trade-off these aspects to reduce strains in the system. In other cases, the contextual variables can also contain a subset of the primary variables themselves. Additionally, many sources of contextual variables can be defined considering application specificities.

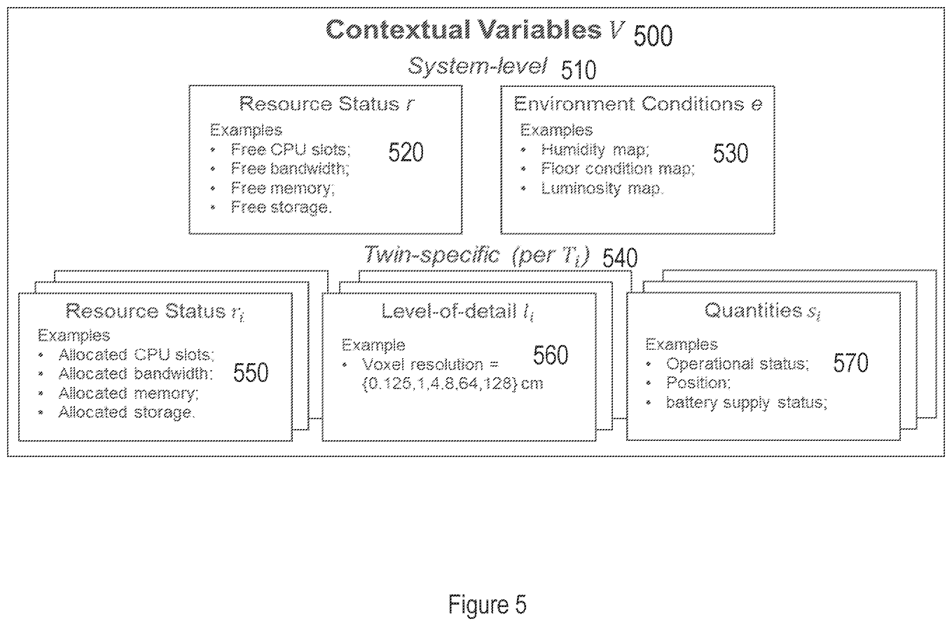

FIG. 5 illustrates one embodiment of contextual variables 500. As shown in FIG. 5, the contextual variables include system-level contextual variables 510 that represent information that applies across the entire edge environment and digital twin specific variables 540 that represent information that only applies to a particular digital twin (i.e., node) in a dynamically informed digital twin network 412. In the illustrated embodiment, the system-level contextual variables 510 include resource status variables 520 and environment condition variables 530. In the illustrated embodiment, the twin specific variables 540 include resource status or cost variables 550, a level-of detail variable 560, and twin quantities variables 570. Each of the different contextual variables 500 will now be explained.

One of the system-level contextual variables 510 are resource status r_{G} variables 520. The resource status variables 520 define the current near-edge node 410 resource usage at the system level. It will be appreciated that the embodiments disclosed herein are not limited to any exact form of r as the resource status variables 520 variables depend on infrastructure implementation details, for example the computing capabilities can be represented as the number of free CPU slots or the number of nodes that a specific virtual machine instance type can be instantiated. However, the resource status variables 520 typically arise in smart environments and comprise the usage of bandwidth; processing capabilities; memory; and storage. It is assumed that r_{G}∈( [symbol] )ⁿ^{ᵣ} is a good general assumption for most applications considered by the embodiments disclosed herein, where [symbol] denotes the set of non-negative real numbers and nᵣ the number of resources within the application.

Another of the system-level contextual variables 510 are environment conditions e variables 530. The environment conditions variables 530 specify the global environment status, as measured by a physical entity, or modelled by the virtual entity. Examples are humidity, floor condition, luminosity, etc. It will be appreciated that the embodiments disclosed herein are not limited to any exact form of the environment conditions variables 530 as these variables can take any reasonable form according to application needs. In some embodiments, the environment conditions variables 530 can be represented as a grid map or in a hierarchical tessellation structure.

One of the twin-specific contextual variables 540 are twin resource status or cost cᵢ∈( [symbol] )ⁿ^{ᵣ} variables 550. The resource use or cost variables 550 specify the resource use of a specific far-edge asset 422 such as allocated CPU slots, bandwidth, memory, and storage. In addition, the resource use or cost variables 550 specify the relevant costs to the system due to the specific far-edge asset 322. Like the system-level contextual variables 510, the embodiments disclosed herein are not limited to specific forms for the resource use or cost variables 550. However, in some embodiments these variables are specified in the same form as the system-level resource status variables 520.

Another of the twin-specific contextual variables 540 is the level-of detail variable 560. The twin level-of-detail variable 560 defines the level-of-detail employed by the twin when modelling geometric descriptions. Therefore, this variable defines a trade-off between the system precision and the strains in the twin (and, therefore, system) resource usage. This can be a set of variables or even a single scalar, depending on the application. For example, when using an SO-map, it may only define the OctoMap tessellation parameters, but may also include other variables such as the ray casting parameters, etc. It is assumed for simplicity that the set of information level [symbol] ᵢ is finite and defined in increasing order of strains in the system. In the illustrated embodiment, twin level-of detail variable is a voxel resolution of the SO-map.

A further of the twin-specific contextual variables 540 are twin quantities qᵢ variables 570. The twin quantities qᵢ variables 570 specify the quantities of the assets 322 and/or their quality, precision, or trustworthiness, as measured by the physical entity, or modelled by the virtual entity. Examples of the twin quantities variables 570 are operational status, position in the environment, battery supply status, etc. Additional variables representing the properties of the environment conditions about the asset can be added: the number of other assets in the surroundings, and local quantities of the environment conditions. An example of a proxy to the quality, precision or trustworthiness is the last time a variable was updated. More specific proxies can be computed provided the specificities of the primary variable.

### C.2 Aspects of a Dynamically Informed Digital Twin

U.S. patent application Ser. No. 18/331,819, filed Jun. 8, 2023, and titled “DYNAMICALLY INFORMED DIGITAL TWINS”, which is incorporated by reference herein in its entirety, introduced the concept of dynamically informed digital twins of a digital twin network such as digital twin network 412 and the ability to dynamically adjust their level-of-detail variable lᵢ 560 as a function of contextual variables 500. Let [symbol] define a Digital Twin Network with nodes described by nᵢ=(pᵢ, Tᵢ, Cᵢ), where pᵢ is the parent node; Tᵢ is the twin unit of node nᵢ; and Cᵢ is a tuple of child nodes. Originally, only assets with the ability to communicate with the near-edge node 410 are considered to be part of [symbol] . The original most basic digital twin is defined as a minimal tuple Tᵢ=(Dᵢ, Sᵢ), with Dᵢ being the DYDT storage, which holds the contextual variables and primary variables, and S, a tuple of services with minimal form Sᵢ= (MSᵢ, CLSᵢ, RESᵢ).

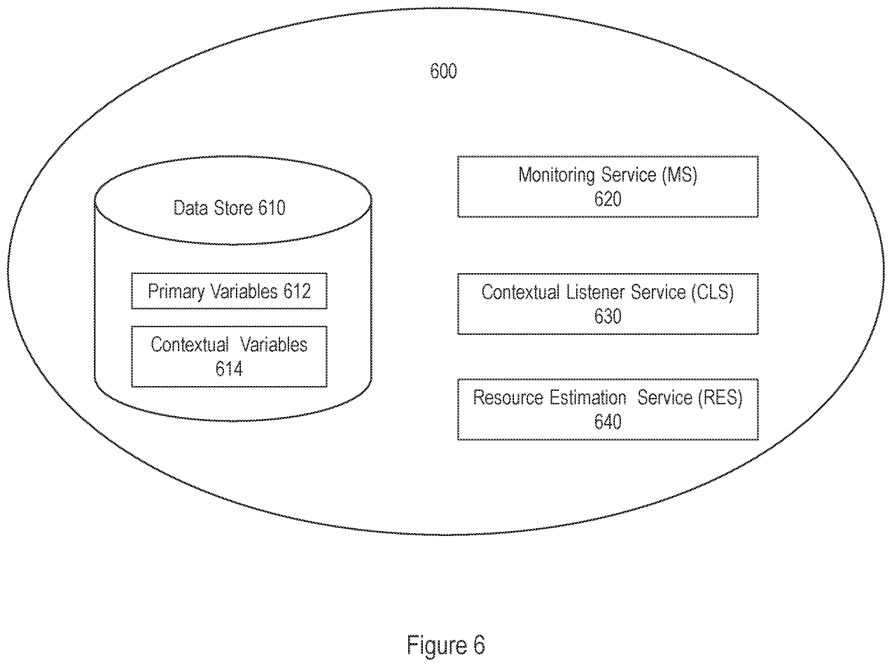

FIG. 6 illustrates an embodiment of a dynamically informed digital twin Tᵢ 600. As illustrated, the dynamically informed digital twin Tᵢ 600 includes a data store 610 that stores primary variables 612, which may correspond to the primary variables previously described and are related to the primary task of the near-edge node 410 and/or the far-edge assets 422. The data storage 610 also stores contextual variables 614, which may correspond to the contextual variables 500 previously described.

The dynamically informed digital twin Tᵢ 600 includes a Monitoring Service (MS) 620. This service plays a core role in the primary goal of ensuring that the twin is synchronized with the network. Importantly for the task of resource allocation, it is responsible for, and the only service with write access to, the contextual variables 500.

The dynamically informed digital twin Tᵢ 600 further includes a Contextual Listener Service (CLS) 630. This service listens to changes in the contextual variables 500 and performs required changes. In the digital twin, it may adjust the digital and physical operation to a new setting. In the embodiments disclosed herein focus on the virtual entity. In the network level, CLS 630 may propagate the contextual variables to other dependent twins.

The dynamically informed digital twin Tᵢ 600 additionally includes a Resource Estimation Service (RES) 640. This service listens to updates in the contextual variables 500, parses them and computes possible operation scenarios and their risks to the operation of the digital twin.

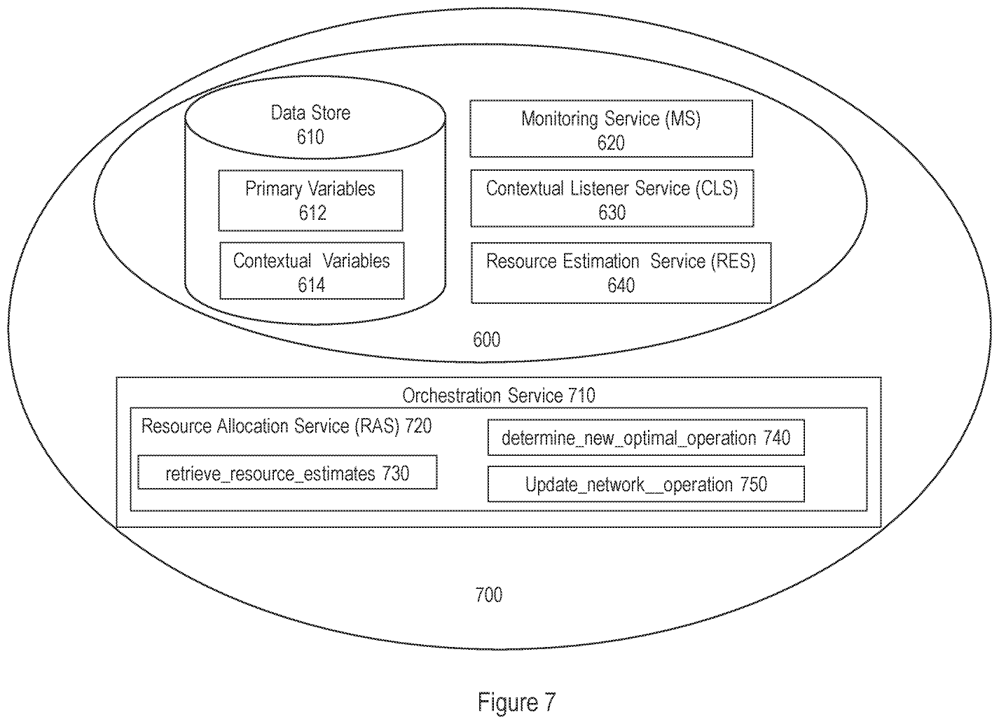

FIG. 7 illustrates an embodiment of a near-edge dynamically informed digital twin (NET) 700. In the embodiments disclosed herein, the near-edge dynamically informed digital twin 700 represents the root node in the dynamically informed digital twin network that is implemented at the near-edge node 410. Accordingly, when the digital twin network is implemented as the structure of a dynamically informed digital twin network to be described in more detail to follow, the near-edge node dynamically informed digital twin 700 represents the root node 802.

All nodes of the dynamically informed digital twin network including the root node include the dynamically informed digital twin 600 framework. Accordingly, the dynamically informed digital twin 600 framework is shown as being included in the near-edge dynamically informed digital twin 700. The dynamically informed digital twin 600 of the near-edge dynamically informed digital twin 700 includes the elements and operates in the manner previously described in relation to FIG. 6.

In the embodiments disclosed herein, the near-edge dynamically informed digital twin 700 is the single digital twin responsible for providing orchestration services for the dynamically informed digital twin network. Accordingly, the near-edge dynamically informed digital twin 700 includes an orchestration service 710 that performs the orchestration services. The orchestration service 710 includes a resource allocation service (RAS) 720 that is used during orchestration.

In the embodiment, the resource allocation service 720 operates mostly in regular time intervals. The frequency of the updates defines a trade-off between the fine-tuning of resource requirements at the expense of availability of resources for the primary tasks performed by the near-edge node and/or the far-edge nodes or assets. While the time interval that is implemented is application specific, periodic updates around 0.1 s, 1 s and 5 s are typical in some embodiments. However, the embodiments disclosed herein are not limited to any particular time interval of the resource allocation service 720.

As illustrated, the resource allocation service 720 includes a retrieve_resource_estimates( [symbol] ) module 730, which in operation retrieves all sets of information levels, costs, and associated risks of the digital twins in the dynamically informed digital twin network. That is, as described in relation to FIG. 6, the resource allocation service 720 receives the information levels, costs, and associated risks from each resource estimation service 640 of each dynamically informed digital twin 600. The retrieve_resource_estimates( [symbol] ) module 730 then builds two dictionaries C and R respectively mapping the digital twins and operation points to costs and associated risks, for example C(Tᵢ, lⱼ)=c_{i,j} and R(Tᵢ, lⱼ)=r_{i,j}. A third dictionary L returns the position of the current information level in [symbol] ᵢ and the information level for each digital twin Tᵢ, i.e., L(Tᵢ)=(pᵢ, lᵢ).

The resource allocation service 720 also includes a determine_new_optimal_operation(L, C, R, r) module 740, which takes as inputs the outputs of the retrieve_resource_estimates module 730 together with the current resource usage status r and determines a new information levels l_{new}. In one embodiment, the optimal information levels l* can be formulated as a constrained optimization problem, i.e.

$${p}^{*} = arg {max}_{p} {\sum }_{i} R ( {T}_{i} , {p}_{i} ) subject to {\sum }_{i} C ( {T}_{i} , {p}_{i} ) \leq {r}_{G}$$

where p={p₀, . . . , [symbol] } are the indexes of the information levels of twins in the network. Then L_{new} is the updated version of L mapping to p* and the respective information levels.

This leads to a combinatorial problem where several approaches can be employed. A particularly simple one leverages on the expectations that not all digital twins should change at once, therefore reducing the possibilities to information levels that are close to the initial information levels. This is a good approximation when the resource allocation service 720 operates in relatively small update intervals with respect to the change in dynamics in the environment. Approaching the problem this way, an algorithm can be defined as follows:

| 1. | Let p = {L(Tᵢ)[0] \| Tᵢ ϵ [symbol] }; i.e., set initial p equal to current operation level for | | | | |
|---|---|---|---|---|---|
| | all twins. If there are multi-dimensional [symbol] ᵢ in the network, i.e., there are more | | | | |
| | than type of level to choose for the twin Tᵢ, then split each dimension [symbol] ᵢ as a | | | | |
| | particular dimension in p, i.e., p = {L(Tᵢ)[0][j] \| Tᵢ ϵ [symbol] , j ϵ {0,...,len( [symbol] ᵢ)}}, | | | | |
| | where len returns the number of dimensions (here we assume [symbol] ᵢ to form a tuple | | | | |
| | of tuples). | | | | |
| 2. | Repeat | | | | |
| | | • | Retrieve c₊ = C(Tᵢ,pᵢ + 1) corresponding to the cost of a one-level | | |
| | | | increase in the information levels, c₋ = C(Tᵢ,pᵢ − 1) the analogous | | |
| | | | variable for a decrease in information level and c = C(Tᵢ,pᵢ). If pᵢ + 1 or | | |
| | | | pᵢ − 1 is invalid, set the value to a placeholder indicating that the choice | | |
| | | | is invalid, i.e., a possible option is to use “not a number”. | | |
| | | • | Likewise, retrieve r₊, r₋ and r; | | |
| | | • | Compute Δ_{c+} = c₊ − c, Δ_{c-} = c₋ − c, Δᵣ₊ = r₊ − r, and Δᵣ₋ = r₋ − r; | | |
| | | • | An increase in information levels should yield maximum risk reduction with | | |
| | | | respect to cost increase. On the other hand, a decrease in information level | | |
| | | | should yield maximum release of resources per risk increase. It is noted | | |
| | | | that cost and resources are multi-dimensional, therefore statistics should | | |
| | | | be employed for comparison purposes. The vectors are normalized with | | |
| | | | respect to the maximum, i.e., [symbol] = Δ_{c+}/cₘₐₓ and so forth, and take the | | |
| | | | s( [symbol] ) = Σ [symbol] as a summary measure of the changes. The following are | | |
| | | | then computed: | | |
| | | | | • | roc = −s( [symbol] )/s( [symbol] ), representing the risk-over-cost gains |
| | | | | | when increasing an information level. |
| | | | | • | cor = −s( [symbol] )/s( [symbol] ), representing the cost-over-risk gains |
| | | | | | when decreasing an information level. |
| | | • | Retrieve the twins that locally results in the best marginal gains in risk. | | |
| | | | | • | i₊ = {i\|rocᵢ > rocₘᵢₙ}, where rocₘᵢₙ determines a minimal value |
| | | | | | in which it is worth increasing information levels and allows to |
| | | | | | avoid operations due to error in estimations. |
| | | | | • | i₋ = {i\|corᵢ > corₘᵢₙ} where corₘᵢₙ results in a similar effect to |
| | | | | | rocₘᵢₙ during operation, but for decreasing information levels. |
| | | | | • | Resolve any i₊ ∩ i₋ ambiguity by keeping the twin index in the list |
| | | | | | resulting in maximum benefits by comparing cor and roc directly. |
| | | • | If i₊ and i₋ are not empty: | | |
| | | | | • | Apply p[i₋]−= 1 and p[i₊]+= 1. Return to step 2 (repeat the |
| | | | | | loop). |

| | | • | Otherwise, break the loop (go to step 3). |
|---|---|---|---|
| 3. | Evaluate if the constraints are satisfied, i.e., ΣᵢC(Tᵢ, pᵢ) ≤ r_{G}: | | |
| | | • | If not satisfied, repeat step 2 until conditions get satisfied, but only seeking |
| | | | i_ in the resources that exceeds the limits. |

| | |
|---|---|
| 4. | Build dictionary L_{new} from final p. |

The resource allocation service 720 also includes an update_network_operation( [symbol] , L_{new}) module 750. The module 750 updates the network level-of-detail by looping over the dynamically informed digital twins 600 and setting the new operation levels. The contextual listeners then operate to inform the physical entities of the new status and the virtual entity to use the appropriated modeling schemes. In addition to the regular time updates, exceptional urgent request can be sent to the RAS. In such cases, RAS skips the retrieve_resource_estimates step and does the computation of the optimal operation considering the last retrieved information.

### D. Aspects of Digital Twin Network Geometric Modeling

### D.1. Aspects of a Digital Twin Network Structure

The embodiments disclosed herein build upon the definition of the digital twin network 412 previously described. Thus, while the definition of the digital twin network 412 was based on communicating assets, the embodiments disclosed herein allow any sematic object in the environment to compose a digital twin in the digital twin network. Thus, the digital twin network can be represented as a graph such as an SO-map 800, in a manner similar to the SO-map or graph 200 previously described. It is noted that every node in the digital twin network N has a twin unit used to represent a semantic object (in leaf nodes of the SO-Map 800) or a set of semantic objects (otherwise) which may also be composed of a semantic object itself.

In the current embodiment, the twin unit most elementary form is modified to have the form Tᵢ=(Dᵢ, Sᵢ, Mᵢ). In the new definition of the twin unit, Mᵢ is a geometric modelling algorithm and its hyperparameters that allow for the geometric modeling of the twin unit as a hierarchical representations such as an OctoMap, although other representations as signed distance fields can also be employed.

The data entity Dᵢ=(Gᵢ, Vᵢ) contains a set of geometric modelling variables Gᵢ=(mᵢ, tᵢ, sᵢ, uᵢ) and contextual variables Vᵢ 500. In the embodiment, mᵢ is the actual twin hierarchical map representation, and the algorithm and parametrization Mᵢ is determined by the contextual variables 500 previously described. If the twin level-of-detail variable lᵢ 560 in Vᵢ is equal to its parent, then mᵢ is a link to the parent pᵢ map mₚᵢ. In the embodiment, tᵢ is the reference frame of the twin (typically represented by its global position and direction), sᵢ is the semantic label, uᵢ is the last update stamp of mᵢ, and Sᵢ=(MSᵢ, CLSᵢ, RESᵢ) as described previously.

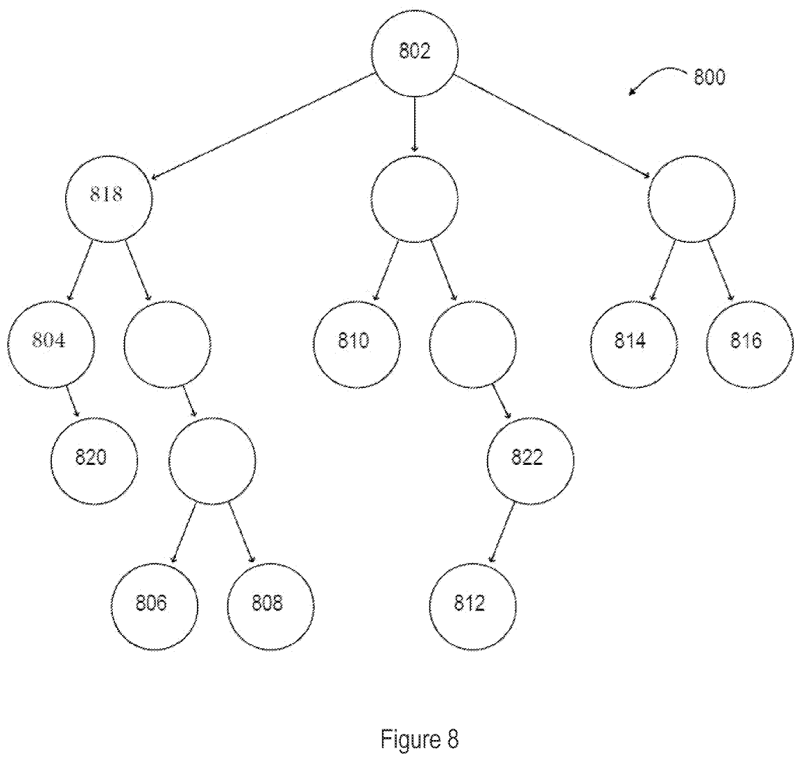

FIG. 8 illustrates an example SO-Map 800 that represents the digital twin network. The SO-Map 800 includes a root node 802, which represents a near-edge twin that provides orchestration services as will be explained in more detail to follow. The root node 802 is a lowest depth node of the SO-Map 800. The leaf nodes 806, 808, 810, 812, and 820 refer to digital twin nodes without child nodes and the remaining nodes (except root node 802) are parent nodes and these nodes represent far-edge twins. The depth d of the SO-Map 800 can be arbitrarily large. The relationships of objects in an environment may vary and change continually. However, SO-Map 800 allows information to be received and distributed efficiently and in a manner that better utilizes available resources at the near-edge and far-edge nodes.

The root node 802 may be n₀=(p₀=Ø, T₀=(D₀=(G₀=(m₀, t₀, s₀, u₀), V₀), S₀, M₀) C₀={nᵢ|pᵢ=n₀}). The node 818 may be represented by n₁= (p₁=n₀, T₁, C₁={nᵢ|pᵢ=n₁, s₁=shelf). This demonstrates that the SO-Map 800 includes a semantic aspect and illustrates that, in some embodiments, each digital twin node may correspond to a digital twin of a specific device or object in the environment. This allows relationships to be reflected in the SO-Map 800 semantically. For example, the semantic label s₂ of the node 804 may be pallet. Because the digital twin node 804 is a child of the digital twin node 818, this may reflect a relationship between the pallet and the shelf. In other words, the pallet is on the shelf. The semantic label s₂ of the digital twin node 820 may be goods. This may reflect that the goods represented by the digital twin node 820 are on the pallet represented by the digital twin node 804, which is on the shelf represented by the digital twin node 818. In another example, the semantic label may also represent an interaction. For example, the semantic label of the digital twin node 822 may be “open box” and the semantic label of the digital twin node 812 may be goods. This may indicate that the box containing the goods is or has been opened.

### D.2 Aspects of Updating the Digital Twin Network.

Representing semantic objects in the digital twin network represented by the SO-map 800 requires the capability to dynamically update the network as they dynamically informed digital twins are identified in or removed from the edge environment. The embodiments disclosed herein take advantage of the SO-map 800 to determine what geometric information pertains to which semantic object (e.g., forklifts, mobile sensors, static sensors, pallets, boxes, goods, etc.) in the environment and to provide the dynamic aspect of the digital twin network, i.e., the ability to create or remove digital twins in the network corresponding to these semantic objects.

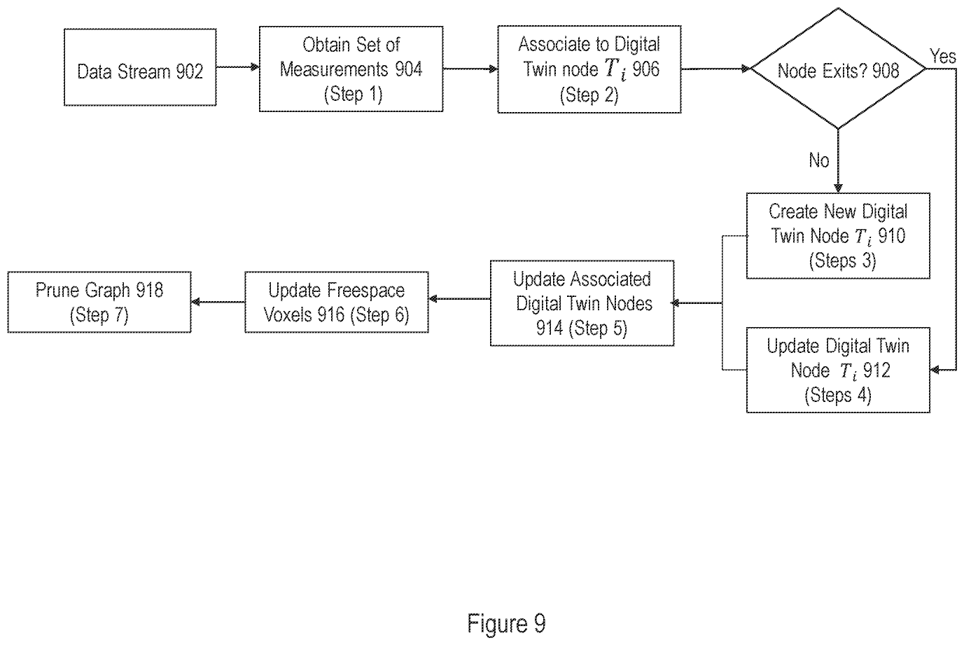

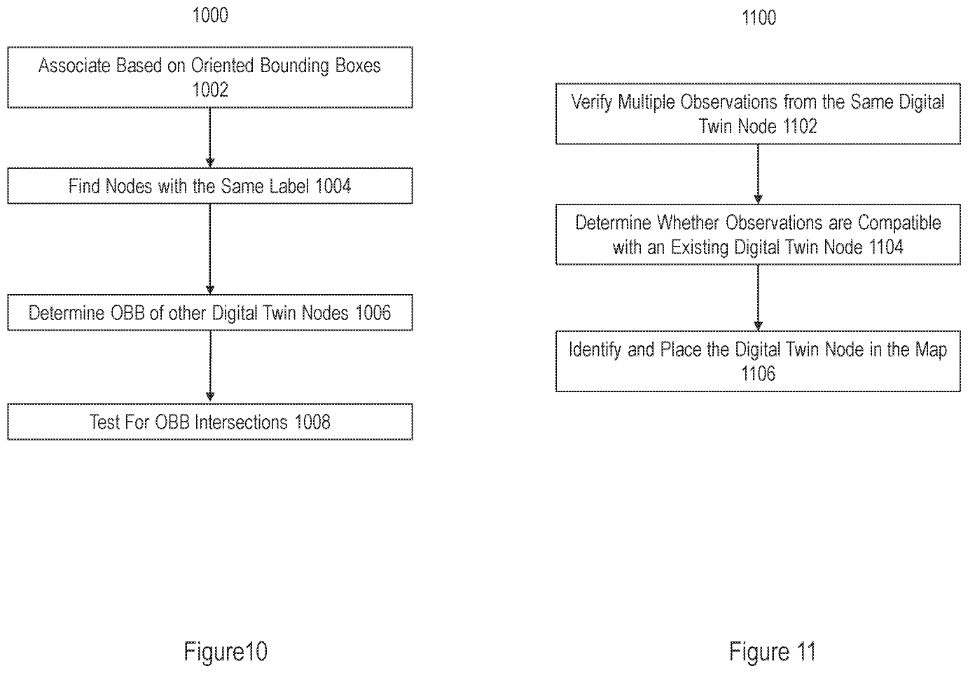

FIG. 9 illustrates a method 900 for updating the digital twin network represented by the SO-map 800. After discussing FIG. 9, FIGS. 10-15, which describe aspects of the method 900 in more detail are discussed.

In the method 900, measurements are obtained 904 or received at the near-edge node. Node information from one or more far-edge nodes (or sensors) is an example of a set of measurements. Each sensor may generate a data stream 902 (e.g., part of the set of measurements). In one example, the raw sensor data is processed at the far-edge nodes. This may include, for example, normalizing the data, grouping the data into sets, or other functions that may depend on the application and/or compute resources available at the far-edge nodes. Other processing that may be performed at the far-edge nodes include compressing the data, sampling the data and sending samples only

In one example, obtaining 904 a set of measurements may include processing data points. The processing depends on the sensor type providing the measurements. For example, LIDAR feeds can be grouped into segments, camera feeds can have its pixels segmented accordingly to semantic, or the like. Likewise, it is possible to process several sensor feeds when performing intensive processing on the near-edge node. For instance, nearby point clouds can be merged before performing segmentation, which may allow more precise results. These operations are application specific but can be assumed to be performed efficiently.

Measurements arranged in this manner allow parallelization to be performed during subsequent processing in the method 900 at the near-edge node, which is an example of a logistics pipeline. The pipeline may define semaphores to wait the processing of nearby observations before updating a node if methods employed during these steps benefits of more information, but other strategies can benefit of full parallelization.

Once the data measurements are obtained, the measurements or other data are associated 906 to a digital twin node Tᵢ in the SO-map 800. More specifically, data may be received from a sensing far-edge node and embodiments of the invention may associate that data to a digital twin node. If a door is closed, for example, a digital twin node approaching the door may be updated accordingly. As previously described, the near-edge node digital twin (NET) receives data from multiple far-edge nodes in the digital twin network and associating data to a digital twin node is performed. In some instances, data may be associated with digital twin nodes and ultimately shared with multiple corresponding far-edge nodes. Data or measurements may be associated with a digital twin node using an association function ƒ_{A}.

While associating the set of measurements, also referred to as observations, to a digital twin node, the method 900 determines at decision block 908 if the digital twin node exists in the SO-map 800. If the digital twin node does not exist (No in decision block 908), the method 900 may create 910 a digital twin node. Thus, if no digital twin node is associated to the set of measurements, digital twin node Tᵢ is created and placed in the SO-map 800.

If the digital twin node does exist (Yes in decision block 908), the method 900 may update 912 mᵢ in digital twin node Tᵢ. In one example, a list of digital twin nodes is evaluated. If an appropriate digital twin node is found, the digital twin node is updated.

Next, associated digital twin nodes are updated 914. This may include updating a child digital twin node and/or digital twin nodes in the SO-map 800. With regard to the OctoMaps in the digital twin nodes, the OctoMaps, including freespace voxels, may be updated 916. Finally, digital twin nodes whose probability of existence is lower than a threshold are pruned 918 from the SO-map 800.

### D.2.1 Digital Twin Node Association (Step 2)

FIG. 10 discloses aspects of an example association method 1000, such as performed in 906 in FIG. 9. In the method 1000, data may be associated 1002 to digital twin node using oriented bounding boxes. An oriented bounding box, in one example, may be viewed as a parallelepiped that may include a digital twin node and a portion of the environment. The form of the association function ƒ_{A} is arbitrary. A possible embodiment can rely on data-based methods for object detection or scene analysis techniques to account for the knowledge carried out by the previous measurements and to correct possible mistakes due to partial observations. For instance, each observation may be tested to each digital twin node with a compatible oriented bounding box and ƒ_{A} would return the digital twin node with highest likelihood that the observation is part of that digital twin node. A similar embodiment could be used to define the form of L and, provided that they share common factors of variation, a multi-task approach can be used to share knowledge between ƒ_{A} and L, allowing to improve the estimate of the semantics label lᵢ and to tackle both tasks at once in 1004.

Digital twin nodes with the same label are identified 1004 and the oriented bounding boxes for other digital twin nodes may be determined 1006. The method 1000 may test for OBB intersections 1008 with regard to the oriented bounding boxes. Ultimately, the method 1000 then returns or identifies the most likely digital twin node (and/or physical node) for the measured data or observations.

A minimum ƒ_{A} likelihood threshold may be defined to allow observations due to new objects to be associated with their own corresponding digital twin nodes. Further, identifying the digital twin node may also include updating aspects of the digital twin nodes, such as some properties of the digital twin nodes' sextuplet (e.g., its label, reference frame, and parent node).

This allows local map updates to be provided to all far-edge nodes if necessary. This may also identify far-edge nodes from which data is retrieved.

### D.2.2 Creating Digital Twin Nodes (Step 3)

FIG. 11 discloses aspects of a method 1100 for creating a digital twin node in the SO-map 800, such as performed in 910 in FIG. 9. Generally, a digital twin node is created when the observations suggest that an object (a physical node) is not represented in the SO-map 800 and is, in effect, a digital twin node. In one example, a digital twin node is created when a digital twin node cannot be located to update. When creating a new digital twin node on the SO-map 800, embodiments disclosed herein determine where to place the digital twin node in the SO-map 800.

In the method 1100, a verification 1102 is performed to ensure that the observations (e.g., the set of measurements) are from the same far-edge node. This process of creating a new digital twin node is a combinatorial problem and embodiments of the invention may rely on heuristic rules to eliminate unlikely combinations. For example, the method may consider the size, bounding boxes, and general shapes of each semantic. This enables a data driven method for each semantic to feed with the observations. This allows the observations or set of measurements that are from the same far-edge or sensing node to be identified. For example, sensor readings of mast height, combined with position data, may indicate that the measurements are from a forklift in a particular area.

Next, the method 1100 determines 1104 whether the observations are compatible with a digital twin node already available in the SO-map 800. In one example, records are kept regarding unobserved changes in digital twin nodes. For example, changes in the digital twin nodes performed by external agents may have been performed in a manner that was not tracked in the map updating operations. Depending on the application, one embodiment may use heuristics. For example, RFID tags can be used to identify the far-edge node. Thus, the measurements may come from a particular far-edge node and the RFID tag may identify the digital twin node in the SO-map 800. In another example, computer vision methods can be used.

The method 1100 then identifies and places 1106 the digital twin node for the far-edge node in the SO-map 800 graph (e.g., r(.,.) plays a central role in this task. One embodiment can be defined based on expert rules. Actions reported by the far-edge node allow to perform node updates on the tree. Main possibilities are two-fold:
A far-edge node reports to be carrying digital twin node Tᵢ, meaning that it is now a child node of the that agent and the SO-map 800 should be updated accordingly;
A far-edge node reports to have placed digital twin node Tᵢ at some position. Proceed by:
   removing digital twin node Tᵢ from the agent child nodes; and
   using r(.,.) to compute its new location on the SO-map 800.

### D.2.3 Updating Digital Twin Nodes (Step 4)

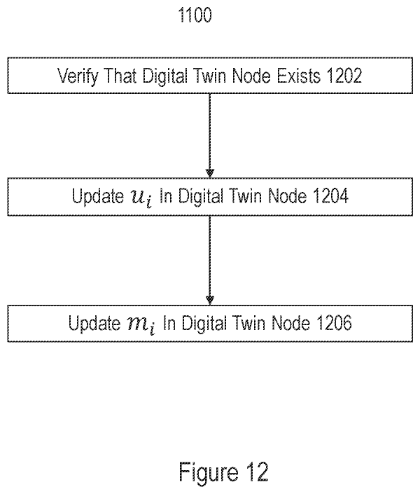

FIG. 12 discloses aspects of a method 1200 for updating a digital twin node in the SO-map 800, such as performed in 912 in FIG. 9. Generally, a digital twin node is updated when the observations discussed in relation to method 1100 verify 1202 that a digital twin node exists in the SO-map 800.

The method 1200 then updates 1204 uᵢ to the current time of execution of the digital twin node update. Then updates 1206 mᵢ in the digital twin node. Concerning the update of mᵢ, one embodiment may rely on direct operations on the OctoMap, i.e., passing out the observations as an update to the framework. Other embodiments may take advantage of semantics knowledge using data-driven approaches to allow estimating the full object shape regardless of occluded regions. If the semantic label sᵢ and the reference frame are to be computed as well, the embodiment may consider a multi-task data-driven method to take advantage of shared factors of variation.

### D.2.4 Updating Associated Digital Twin Nodes (Step 5)

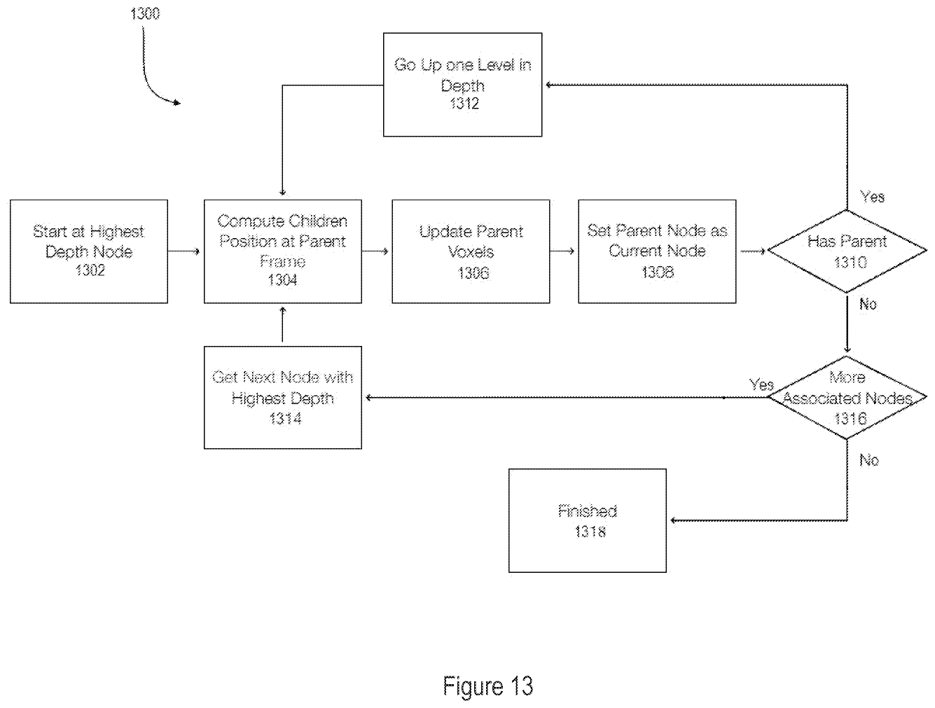

Once the digital twin node creation/update operation has been performed, associated digital twin nodes are updated. FIG. 13 discloses aspects of a method 1300 for updating associated digital twin nodes, such as performed in 914 in FIG. 9. Associated digital twin nodes may include child and/or parent digital twin nodes. Generally, updating associated v nodes include updating properties uᵢ and mᵢ and/or other properties. The property uᵢ is set to a current time of execution of the digital twin node update. With regard to updating the property mᵢ, this may include distributing the observations to far-edge nodes based on the SO-map 800 as a local map update. Thus, the local OctoMaps are updated.

In one example, updating the parent digital twin nodes of each associated digital twin is performed so that the digital twin nodes present the actual observed state of the environment, including at the root digital twin node. The update may be performed as a bottom-up approach, starting at the digital twin node in the highest depth.

One aspect of embodiments of the invention is updating the parents of each associated digital twin node so that they present the actual observed state of the environment, particularly the root digital twin node. The update is carried out in a bottom-up approach, starting at the with highest depth. This update keeps the correct level-of-detail for each semantic in the parent digital twin nodes. If a parent digital twin node has higher level-of-detail than a child digital twin node, the parent may represent the child with its own details. Otherwise, the child will be represented with lower level-of-detail on the parent digital twin.

More specifically, the method 1300 starts 1302 updating at a highest depth digital twin node. Next, the positions of children digital twin nodes are determined 1304 at the parent frame using tᵢ (the reference frame of the digital twin node). Parent voxels are updated next 1306. The parent digital twin node is then set 1308 as the current digital twin node. If the current digital twin node has a parent (current digital twin node has a parent (Y at 1310), go up one level in depth 1312 and repeat the method. If the current digital twin node does not have a parent (N at 1310) and there are more associated digital twin nodes (Y at 1316), the digital twin node at the next highest depth is obtained 1314 and the method returns to 1304. Otherwise, the method 1300 finished 1318.

When sets of measurements are received, these measurements or observations provide information related to both free and occupied space. Updating free and occupied space on a local map corresponds to a fraction of the knowledge obtained in an observation. However, free space observations may span beyond the boundaries of the node associated with the observed points regarding occupied space. In one example, free space voxels are updated at digital twin nodes using a top-down approach. Generally, starting at the root digital twin node, a ray casting operation may be performed to update free space voxels of impacted digital twin nodes.

### D.2.5 Updating Associated Digital Twin Nodes (Step 6)

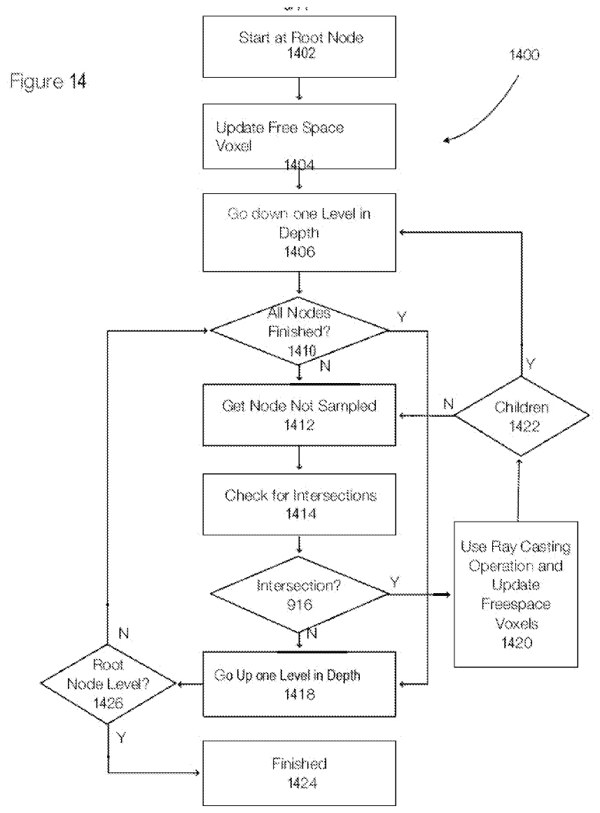

FIG. 14 discloses aspects of a method 1400 for updating other digital twin nodes, such as performed in 916 in FIG. 9. The measurements may provide information related to both free and occupied space. FIG. 14 is a method for updating only free space voxels at digital twin nodes affected by the observations or measurements in a top-down approach. The method 1400 starts 1402 at a root digital twin node. Using ray casting or other method, free space voxels are updated 1404 for the digital twin node.

The method 1400 then goes down 1406 one level in depth. Next, a digital twin node that was not sampled with respect to updating the digital twin nodes is retrieved 1412 and the retrieved digital twin node is checked for intersections of ray casting and oriented bounding box 1414. If there is an intersection (Y at 1416), ray casting 1420 is performed to update freespace voxels. If there are children digital twin nodes (Y at 1422), the method 1400 goes down one level in depth 1406. If there are no children digital twin nodes (N at 1422), another digital twin node that was not previously sampled is retrieved and a similar process of checking 1414 for intersections is performed.

If there is no intersection (N at 1416), the method goes up one level in depth 1418. If at the root node level (Y at 1426), the method 1400 finished 1424. If not (N at 1426), the method repeats back to 1410. This method 1400 updates freespace voxels throughout the full SO-map 800 structure for digital twin nodes that are not digital twin nodes previously sampled or updated in 914.

### D.2.6 Pruning Digital Twin Nodes (Step 7)

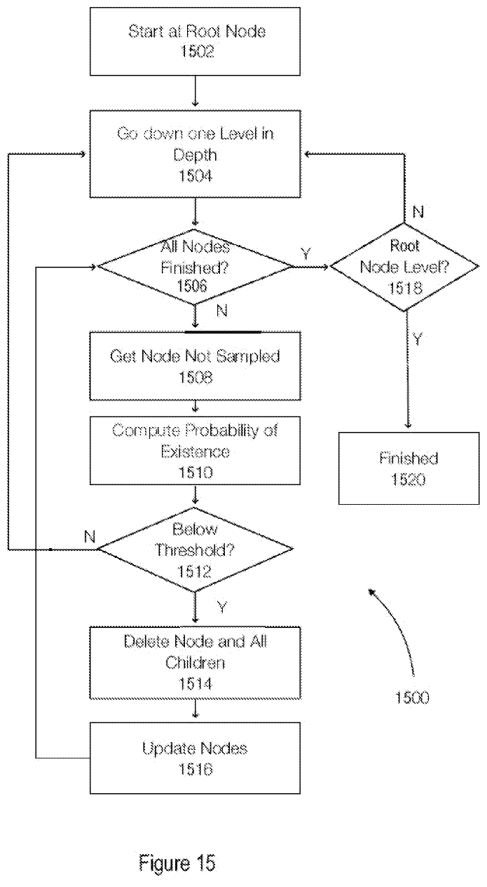

FIG. 15 discloses aspects of a method 1500 for pruning nodes from the SO-map 800 such as performed in 918 in FIG. 9. Unobserved changes in environment may require the ability to completely remove objects from the representation of the global state. Because all nodes are updated with their children information, a top-down approach may be performed to prune nodes from the SO-map 800.

The method 1500 starts 1502 at the root digital twin node. After going down 1504 one level in depth and determining that all digital twin nodes have not been processed (N at 1506), a digital twin node that was not sampled in the context of updating/creating digital twin nodes is retrieved or accessed in 1508. The probability of existence is then determined 1510. If below a threshold (Y at 1512), the digital twin node and all children digital twin nodes thereof are deleted 1514 and the digital twin nodes are updated 1516 as needed. The method then returns to 1506 to determine whether all digital twin nodes have been processed.

If the existence of a digital twin node is not below a threshold (N at 1512), the method 1500 goes down 1504 a level in depth and continues the method. When all digital twin nodes are processed (Y at 1506) and the method is at the at the root node level (Y at 1518), the method ends. Otherwise, the method 1500 goes down a level in depth 1504 and continues as discussed.

### E. Example Embodiments

Following are some further example embodiments of the invention. These are presented only by way of example and are not intended to limit the scope of the invention in any way.

Embodiment 1. A method comprising: performing geometrical modeling of a digital twin network, the digital twin network including a dynamically informed digital twin of a near-edge node and one or more dynamically informed digital twins of a plurality of far-edge nodes, wherein each dynamically informed digital twin is at least partially defined by a set of geometrical modeling variables and contextual variables that are used to map each dynamically informed digital twin to a graph, the geometrical modeling comprising: obtaining a set of measurements from sensors in an edge environment that includes the near-edge and the plurality of far-edge nodes; associating the set of measurements to a digital twin node in the graph, wherein the digital twin node corresponds to one of the far-edge nodes; updating the digital twin node in the graph associated with the set of measurements and updating the corresponding far-edge node with a local update; updating digital twin nodes associated with the digital twin node that was updated; and updating digital twin nodes not associated with the digital twin node that was updated.

Embodiment 2. The method of any previous embodiment, wherein each of the digital twin nodes is represented in their minimal form by a triplet including a data entity, a set of services, an a geometric modeling algorithm, and the data entity is composed of a map, a frame of reference, a parent node, and an update timestamp as the geometric modelling variables and the contextual variables.

Embodiment 3. The method of any previous embodiment, wherein the map in each of the digital twin node comprises an octomap.

Embodiment 4. The method of any previous embodiment, further comprising pruning the graph of digital twin nodes whose likelihood of existing are below a threshold value.

Embodiment 5. The method of any previous embodiment, further comprising creating a new digital twin node in the graph when the set of measurements are not associated with an existing graph node in the graph.

Embodiment 6. The method of any previous embodiment, wherein updating the digital twin node includes verifying that the set of measurements are from a particular semantic class and determining whether the set of measurements are compatible with an existing graph node in the graph.

Embodiment 7. The method of any previous embodiment, wherein each dynamically informed digital twin comprises: a resource estimation service configured to evaluate one or more possible operational conditions of the dynamically informed digital twin based at least in part on one or more contextual variables that represent operating properties of the dynamically informed digital twin; a monitoring service configured to receive updated information levels from an orchestration service, the updated information levels defining an amount of resources the dynamically informed digital twin will use in the performance of one or more primary tasks; and a contextual listener service configured to parse the updated information levels and to inform a physical entity associated with the dynamically informed digital twin to adjust one or more sampling properties or increase or decrease its activity and to inform the dynamically informed digital twin to modify one or more information processing methods to thereby adjust an overall resource usage in the digital twin network

Embodiment 8. The method of any previous embodiment, wherein the dynamically informed digital twin of the near-edge node further comprises the orchestration service, the orchestration service comprising: a resource allocation service configured to: receive from each resource estimation service of each dynamically informed digital twin the one or more possible operational conditions; determine the updated information levels; and provide the updated information levels to the monitoring service of each dynamically informed digital twin.

Embodiment 9. The method of any previous embodiment, wherein the contextual variables include system level contextual variables and dynamically informed digital twin specific contextual variables.

Embodiment 10. The method of any previous embodiment, wherein the system level contextual variables include resource status variables for the digital twin network and environmental condition variables for the digital twin network and the dynamically informed digital twin specific contextual variables include resource status variables for the dynamically informed digital twin, level-of-detail variables, and quantities variables.

Embodiment 11. A system, comprising hardware and/or software, operable for performing any of the operations, methods, or processes, or any portion of any of these, or any combination thereof, disclosed herein.

Embodiment 12. A non-transitory storage medium having stored therein instructions that are executable by one or more hardware processors to perform operations comprising the operations of any one or more of embodiments 1-10.

### Example Computing Devices and Associated Media

The embodiments disclosed herein may include the use of a special purpose or general-purpose computer including various computer hardware or software modules, as discussed in greater detail below. A computer may include a processor and computer storage media carrying instructions that, when executed by the processor and/or caused to be executed by the processor, perform any one or more of the methods disclosed herein, or any part(s) of any method disclosed.

As indicated above, embodiments within the scope of the present invention also include computer storage media, which are physical media for carrying or having computer-executable instructions or data structures stored thereon. Such computer storage media may be any available physical media that may be accessed by a general purpose or special purpose computer.

By way of example, and not limitation, such computer storage media may comprise hardware storage such as solid state disk/device (SSD), RAM, ROM, EEPROM, CD-ROM, flash memory, phase-change memory (“PCM”), or other optical disk storage, magnetic disk storage or other magnetic storage devices, or any other hardware storage devices which may be used to store program code in the form of computer-executable instructions or data structures, which may be accessed and executed by a general-purpose or special-purpose computer system to implement the disclosed functionality of the invention. Combinations of the above should also be included within the scope of computer storage media. Such media are also examples of non-transitory storage media, and non-transitory storage media also embraces cloud-based storage systems and structures, although the scope of the invention is not limited to these examples of non-transitory storage media.

Computer-executable instructions comprise, for example, instructions and data which, when executed, cause a general-purpose computer, special purpose computer, or special purpose processing device to perform a certain function or group of functions. As such, some embodiments of the invention may be downloadable to one or more systems or devices, for example, from a website, mesh topology, or other source. As well, the scope of the invention embraces any hardware system or device that comprises an instance of an application that comprises the disclosed executable instructions.

Although the subject matter has been described in language specific to structural features and/or methodological acts, it is to be understood that the subject matter defined in the appended claims is not necessarily limited to the specific features or acts described above. Rather, the specific features and acts disclosed herein are disclosed as example forms of implementing the claims.

As used herein, the term module, component, engine, agent, or the like may refer to software objects or routines that execute on the computing system. The different components, modules, engines, and services described herein may be implemented as objects or processes that execute on the computing system, for example, as separate threads. While the system and methods described herein may be implemented in software, implementations in hardware or a combination of software and hardware are also possible and contemplated. In the present disclosure, a ‘computing entity’ may be any computing system as previously defined herein, or any module or combination of modules running on a computing system.

In at least some instances, a hardware processor is provided that is operable to carry out executable instructions for performing a method or process, such as the methods and processes disclosed herein. The hardware processor may or may not comprise an element of other hardware, such as the computing devices and systems disclosed herein.

In terms of computing environments, embodiments of the invention may be performed in client-server environments, whether network or local environments, or in any other suitable environment. Suitable operating environments for at least some embodiments of the invention include cloud computing environments where one or more of a client, server, or other machine may reside and operate in a cloud environment.

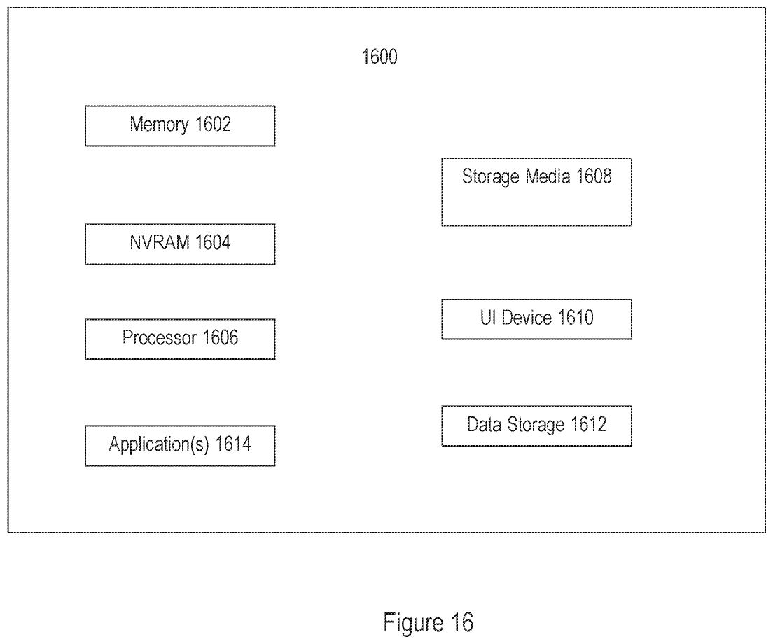

With reference briefly now to FIG. 16, any one or more of the entities disclosed, or implied, by the figures and/or elsewhere herein, may take the form of, or include, or be implemented on, or hosted by, a physical computing device, one example of which is denoted at 1600. As well, where any of the aforementioned elements comprise or consist of a virtual machine (VM), that VM may constitute a virtualization of any combination of the physical components disclosed in FIG. 16.

In the example of FIG. 16, the physical computing device 1600 includes a memory 1602 which may include one, some, or all, of random access memory (RAM), non-volatile memory (NVM) 1604 such as NVRAM for example, read-only memory (ROM), and persistent memory, one or more hardware processors 1606, non-transitory storage media 1608, UI device 1610, and data storage 1612. One or more of the memory components 1602 of the physical computing device 1600 may take the form of solid-state device (SSD) storage. As well, one or more applications 1614 may be provided that comprise instructions executable by one or more hardware processors 1606 to perform any of the operations, or portions thereof, disclosed herein.

Such executable instructions may take various forms including, for example, instructions executable to perform any method or portion thereof disclosed herein, and/or executable by/at any of a storage site, whether on-premises at an enterprise, or a cloud computing site, client, datacenter, data protection site including a cloud storage site, or backup server, to perform any of the functions disclosed herein. As well, such instructions may be executable to perform any of the other operations and methods, and any portions thereof, disclosed herein.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method comprising:
performing geometrical modeling of a digital twin network, the digital twin network including a dynamically informed digital twin of a near-edge node and one or more dynamically informed digital twins of a plurality of far-edge nodes, wherein each dynamically informed digital twin is at least partially defined by a set of geometrical modeling variables and contextual variables that are used to map each dynamically informed digital twin to a graph, the geometrical modeling comprising:
obtaining a set of measurements from sensors in an edge environment that includes the near-edge and the plurality of far-edge nodes;
associating the set of measurements to a digital twin node in the graph, wherein the digital twin node corresponds to one of the far-edge nodes;
updating the digital twin node in the graph associated with the set of measurements and updating the corresponding far-edge node with a local update;
updating digital twin nodes associated with the digital twin node that was updated; and
updating digital twin nodes not associated with the digital twin node that was updated.

2. The method of claim 1, wherein each of the digital twin nodes is represented in their minimal form by a triplet including a data entity, a set of services, an a geometric modeling algorithm, and the data entity is composed of a map, a frame of reference, a parent node, and an update timestamp as the geometric modelling variables and the contextual variables.

3. The method of claim 2, wherein the map in each of the digital twin node comprises an octomap.

4. The method of claim 1, further comprising pruning the graph of digital twin nodes whose likelihood of existing are below a threshold value.

5. The method of claim 1, further comprising creating a new digital twin node in the graph when the set of measurements are not associated with an existing graph node in the graph.

6. The method of claim 1, wherein updating the digital twin node includes verifying that the set of measurements are from a particular semantic class and determining whether the set of measurements are compatible with an existing graph node in the graph.

7. The method of claim 1, wherein each dynamically informed digital twin comprises:
a resource estimation service configured to evaluate one or more possible operational conditions of the dynamically informed digital twin based at least in part on one or more contextual variables that represent operating properties of the dynamically informed digital twin;
a monitoring service configured to receive updated information levels from an orchestration service, the updated information levels defining an amount of resources the dynamically informed digital twin will use in the performance of one or more primary tasks; and
a contextual listener service configured to parse the updated information levels and to inform a physical entity associated with the dynamically informed digital twin to adjust one or more sampling properties or increase or decrease its activity and to inform the dynamically informed digital twin to modify one or more information processing methods to thereby adjust an overall resource usage in the digital twin network.

8. The method of claim 7, wherein the dynamically informed digital twin of the near-edge node further comprises an orchestration service, the orchestration service comprising:
a resource allocation service configured to:
receive from each resource estimation service of each dynamically informed digital twin the one or more possible operational conditions;
determine updated information levels; and
provide the updated information levels to the monitoring service of each dynamically informed digital twin.

9. The method of claim 1, wherein the contextual variables include system level contextual variables and dynamically informed digital twin specific contextual variables.

10. The method of claim 9, wherein the system level contextual variables include resource status variables for the digital twin network and environmental condition variables for the digital twin network and the dynamically informed digital twin specific contextual variables include resource status variables for the dynamically informed digital twin, level-of-detail variables, and quantities variables.

11. A non-transitory storage medium having stored therein instructions that are executable by one or more hardware processors to perform operations comprising:
performing geometrical modeling of a digital twin network, the digital twin network including a dynamically informed digital twin of a near-edge node and one or more dynamically informed digital twins of a plurality of far-edge nodes, wherein each dynamically informed digital twin is at least partially defined by a set of geometrical modeling variables and contextual variables that are used to map each dynamically informed digital twin to a graph, the geometrical modeling comprising:
obtaining a set of measurements from sensors in an edge environment that includes the near-edge and the plurality of far-edge nodes;
associating the set of measurements to a digital twin node in the graph, wherein the digital twin node corresponds to one of the far-edge nodes;
updating the digital twin node in the graph associated with the set of measurements and updating the corresponding far-edge node with a local update;
updating digital twin nodes associated with the digital twin node that was updated; and
updating digital twin nodes not associated with the digital twin node that was updated.

12. The non-transitory storage medium of claim 11, wherein each of the digital twin nodes is represented in their minimal form by a triplet including a data entity, a set of services, an a geometric modeling algorithm, and the data entity is composed of a map, a frame of reference, a parent node, and an update timestamp as the geometric modelling variables and the contextual variables.

13. The non-transitory storage medium of claim 12, wherein the map in each of the digital twin node comprises an octomap.

14. The non-transitory storage medium of claim 11, further comprising pruning the graph of digital twin nodes whose likelihood of existing are below a threshold value.

15. The non-transitory storage medium of claim 11, further comprising creating a new digital twin node in the graph when the set of measurements are not associated with an existing graph node in the graph.

16. The non-transitory storage medium of claim 11, wherein updating the digital twin node includes verifying that the set of measurements are from a particular semantic class and determining whether the set of measurements are compatible with an existing graph node in the graph.

17. The non-transitory storage medium of claim 11, wherein each dynamically informed digital twin comprises:
a resource estimation service configured to evaluate one or more possible operational conditions of the dynamically informed digital twin based at least in part on one or more contextual variables that represent operating properties of the dynamically informed digital twin;
a monitoring service configured to receive updated information levels from an orchestration service, the updated information levels defining an amount of resources the dynamically informed digital twin will use in the performance of one or more primary tasks; and
a contextual listener service configured to parse the updated information levels and to inform a physical entity associated with the dynamically informed digital twin to adjust one or more sampling properties or increase or decrease its activity and to inform the dynamically informed digital twin to modify one or more information processing methods to thereby adjust an overall resource usage in the digital twin network.

18. The non-transitory storage medium of claim 17, wherein the dynamically informed digital twin of the near-edge node further comprises an orchestration service, the orchestration service comprising:
a resource allocation service configured to:
receive from each resource estimation service of each dynamically informed digital twin the one or more possible operational conditions;
determine the updated information levels; and
provide the updated information levels to the monitoring service of each dynamically informed digital twin.

19. The non-transitory storage medium of claim 11, wherein the contextual variables include system level contextual variables and dynamically informed digital twin specific contextual variables.

20. The non-transitory storage medium of claim 19, wherein the system level contextual variables include resource status variables for the digital twin network and environmental condition variables for the digital twin network and the dynamically informed digital twin specific contextual variables include resource status variables for the dynamically informed digital twin, level-of-detail variables, and quantities variables.
